(19) United States
(12) Patent Application Publication
(10) Pub. No.: US 2013/0146554 A1
(43) Pub. Date: Jun. 13, 2013

(54) SOLAR MODULE MOUNTING APPARATUS

(71) Applicants: Jason Berry, Sausalito, CA (US); Eric Horn, Alamo, CA (US); Ronald A. Bullock, Tracy, CA (US); Alex C. Meyer, San Francisco, CA (US)

(72) Inventors: Jason Berry, Sausalito, CA (US); Eric Horn, Alamo, CA (US); Ronald A. Bullock, Tracy, CA (US); Alex C. Meyer, San Francisco, CA (US)

(21) Appl. No.: 13/494,298

(22) Filed: Jun. 12, 2012

Related U.S. Application Data
(60) Provisional application No. 61/497,384, filed on Jun. 15, 2011.
(60) Provisional application No. 61/507,014, filed on Jul. 12, 2011.

(51) Int. Cl. H01L 31/042

(52) U.S. Cl. CPC H01L 31/0422
USPC 211/175; 211/182

(57) ABSTRACT

A universal solar module mounting system includes a plurality of vertical posts and a plurality of parallel and horizontal beams. Each of the beams is supported above the ground by one or more of the posts. Purlins are coupled to the beams with purlin clips and fasteners. The purlin clips or beams can include parallel and adjacent slots. Fasteners are placed through the slots and the slots allow the purlins to be positioned on the beams to properly support the specific solar modules being used. Mounting components are used to secure each of the solar modules to two or more of the purlins.

### CROSS REFERENCE TO RELATED APPLICATION

This application claims priority to U.S. Provisional Patent Application No. 61/497,384, “Modular Horizontal T-Structure For Parking PV Array” filed Jun. 15, 2011 and U.S. Provisional Patent Application No. 61/507,014, “Modular Horizontal T-Structure For Parking PV Array” filed Jul. 12, 2011. U.S. Provisional Patent Application Nos. 61/497,384 and 61/507,014 are hereby incorporated by reference.

### BACKGROUND

A solar module is a packaged interconnected assembly of solar cells, also known as photovoltaic cells. The solar module can be used as a component of a larger photovoltaic system to generate and supply electricity in commercial and residential applications. Most solar module arrays use an inverter to convert the direct current (DC) power produced by the modules into alternating current (AC) that can power lights, motors, and other loads. The solar modules in a solar module array can be connected in series to obtain the desired voltage and then the series coupled groups of modules can be connected in parallel to allow the system to produce more current.

Each solar module in the solar module array can be attached to a fixed mount that tilts the solar module towards the yearly average position of the midday sun. For example, the modules installed in the northern hemisphere may face due south and conversely, southern hemisphere solar modules may face north. The tilt angle of the solar modules can be fixed and can be set to give optimal array output during the peak electrical demand portion of a typical year. Each of the solar modules in the solar module array is mounted to a stable support structure that can hold the solar modules in the desired position and elevate each of the solar module off the ground. For example, for improved space efficiency, the array of solar modules can be mounted on elevated posts over a car parking area so that cars can be parked in shaded areas under the solar modules which are fully exposed to the solar energy. This use can provide the dual benefit of providing sun protection to keep the cars cooler and utilizing the exposed parking lot area for the collection of solar energy.

A problem with existing solar installations is that the primary mounting structure is built to a specific size solar module. Thus, the solar module dimensions must be known before the mounting structure can be completed. If the primary mounting structure is built for a first solar module and the order is changed to a second solar module, the mounting devices on the structure must be removed and replaced with new mounting devices for the second solar module. In most cases, the mounting hardware can include welded components that must be removed by grinding or cutting and then replacement. A similar reconfiguration procedure is needed if an older inefficient solar module is replaced with a newer more efficient solar module that has a different size. In order to eliminate these problems, a universal solar module mounting system is needed that is compatible with and can securely mount many different sized solar modules to the mounting structure.

### SUMMARY OF THE INVENTION

The present invention is directed towards a universal solar module mounting system which can be used to secure solar modules having different sizes to mounting brackets. The mounting brackets can include a plurality of parallel beams that are horizontal or angled so that the modules are positioned for maximum solar exposure. Each of the beams is supported by one or more vertical posts. The universal mounting system can include a plurality of purlins that are placed over the beams in a substantially perpendicular orientation and secured to the beams with purlin clips. The purlin clips can be L shaped with a vertical portion and a horizontal portion. The vertical and horizontal portions of the purlin clip can also have mounting holes that can accommodate fasteners. The vertical portion can be fastened to the purlin and the horizontal portion can be fastened to the beam with self tapping screws, threaded bolts or bolts which are coupled to nuts.

The solar modules are secured to the tops of two or more purlins that run across the widths of the modules. Each solar module can have a different mounting position for the purlins. In an embodiment, the purlin clip can include slots that allow the purlin to be moved within a range of positions to accommodate the specific mounting requirements of the solar modules being used. In other embodiments, slots can be formed in the beams to allow the purlins to move in a range of positions relative to the beams. Once the purlins are properly positioned, they are secured in place with fasteners.

In an embodiment, the solar module mounting system includes mounting components at a plurality of connection points. The mounting components can include a spacer clip, a module clip and a fastener. The module clip can be a “T” shaped structure that engages the upper surface of the solar module and the spacer clip can be positioned between the bottom surface of the module and the top surface of the purlin. In an embodiment, the lower portion of the module clip and the spacer tabs extending from the spacer clip can have approximately the same widths. The module clip and spacer tabs can function as spacing guides to properly separate the two adjacent solar modules. In an embodiment, the spacer clip can include engagement tabs which fit into corresponding holes in the bottom surface of the solar modules. The engagement tabs can prevent the solar modules from sliding out of the proper mounting position on the mounting bracket. A fastener can pass through holes in the module clip and the spacer clip and be threaded into the purlin or a nut on the opposite side of the purlin. The fastener can then be tightened to the proper torque to secure the solar module to the mounting system.

If the solar modules need to be replaced, the fasteners that secure the module clips and spacer clips to the purlin can be removed to free the solar modules. The proper purlin locations can be determined for the new solar modules and the bolts securing the purlin clips to the beams can be loosened and the purlins can slide to the proper mounting positions for the new solar modules. Once the purlins are properly positioned on the beams, the bolts can be tightened to secure the purlins to the beams. The new modules can then be mounted on the purlins by securing the module clips and the spacer clips to the purlins with fasteners. This process is a significant improvement over the prior art systems which can require cutting the attachment points to move the purlins and module clips.

### BRIEF DESCRIPTION OF THE DRAWINGS

FIG. 1 illustrates a side view of an embodiment of the solar module mounting system;

FIG. 2 illustrates a top view of an embodiment of the solar module mounting system;

FIG. 3 illustrates a top view of an embodiment of a moveable purlin mechanism;

FIG. 4 illustrates a cross section view of an embodiment of a moveable purlin mechanism;

FIG. 5 illustrates a top view of an embodiment of a moveable purlin mechanism;

FIG. 6 illustrates a cross section view of an embodiment of a moveable purlin mechanism;

FIG. 7 illustrates a side view of an embodiment of the solar module mounting system;

FIGS. 8 and 9 illustrate different embodiments of purlin clips;

FIG. 10 illustrates an embodiment of the module clip;

FIG. 11 illustrates an embodiment of the spacer clip; and

FIG. 12 illustrates a flowchart of the steps for installing and changing the solar modules coupled to the mounting system.

### DETAILED DESCRIPTION

The present invention is directed towards a universal system for mounting solar modules to support structures that can accommodate a wide range of module sizes. This universal sizing feature is important because it allows a standard support structure to be fabricated that will work with all common sized solar modules currently being produced. This universal system allows the primary support structures to be built and installed without knowing the exact dimensions of the solar modules that will be mounted on the support structures. This is an improvement over fixed mounting systems which are designed for a specific solar module which cannot be completely constructed until the exact dimensions of the solar modules are known. The inventive system also allows the modules to be replaced at any time with solar modules that have different dimensions.

When solar module installations are ordered, the end user may only care about the price and power output of the installed solar system, the type or brand of solar modules used in the system may not be important to the end user. However, the contractor installing the solar module system will try to make the most amount of profit from the installation and may purchase solar modules that have the best cost per power output ratio. Because there are many solar companies, the manufacturer who has the best price per power output may change regularly and the solar modules may only be purchased just before they are to be mounted on the support structures. By using the inventive universal module mounting system, the mounting structure can be completely built without knowing the size of the solar modules that are to be installed.

Solar modules are increasing in efficiency each year and in many older solar module installations, there can be a significant economic benefit to replacing the older solar modules with newer modules that have improved efficiency. The universal sizing system also allows the existing support structure to be changed to properly secure new solar modules with new module dimensions without a significant amount of reconstruction of the support structure. In contrast, existing solar module support structures are made for a predetermined solar module having specific length, width and thickness dimensions. If the solar modules are replaced with newer modules that have different dimensions, the mounting hardware of the inventive system can simply be released to remove the old modules and adjusted to accommodate the different size of the new modules. This flexibility in module compatibility is a significant improvement over existing solar module mounting systems.

Table 1 includes a listing of solar module manufacturers and the dimensions of their solar modules. Although many of the modules are similar in size, none of the manufacturers make the same sized solar modules. Thus, a mounting system made for a solar module made by a first manufacturer will not be compatible with a solar module made by a second manufacturer.

TABLE 1

| MANUFAC- | LENGTH | WIDTH | WEIGHT | POWER OUTPUT |
|---|---|---|---|---|
| TURER | (Inches) | (Inches) | (lbs) | (Watts) |
| BP Solar | 65.63 | 39.37 | 35.3 | 225 |
| Canadian | 64.49 | 38.66 | 44.1 | 240 |
| Kyocera | 65.43 | 39.41 | 46.3 | 240 |
| Sanyo | 62.20 | 31.40 | 35.3 | 225 |
| Sharp | 64.60 | 39.10 | 41.9 | 240 |
| SolarWorld | 65.94 | 39.41 | 46.7 | 240 |
| Solon | 64.70 | 39.37 | 51.81 | 230 |
| SunPower | 61.39 | 31.42 | 33.1 | 240 |
| SunTech | 65.60 | 39.00 | 44.1 | 240 |
| Trina | 64.95 | 39.05 | 43.0 | 240 |
| Yinli | 64.96 | 38.98 | 43.7 | 240 |

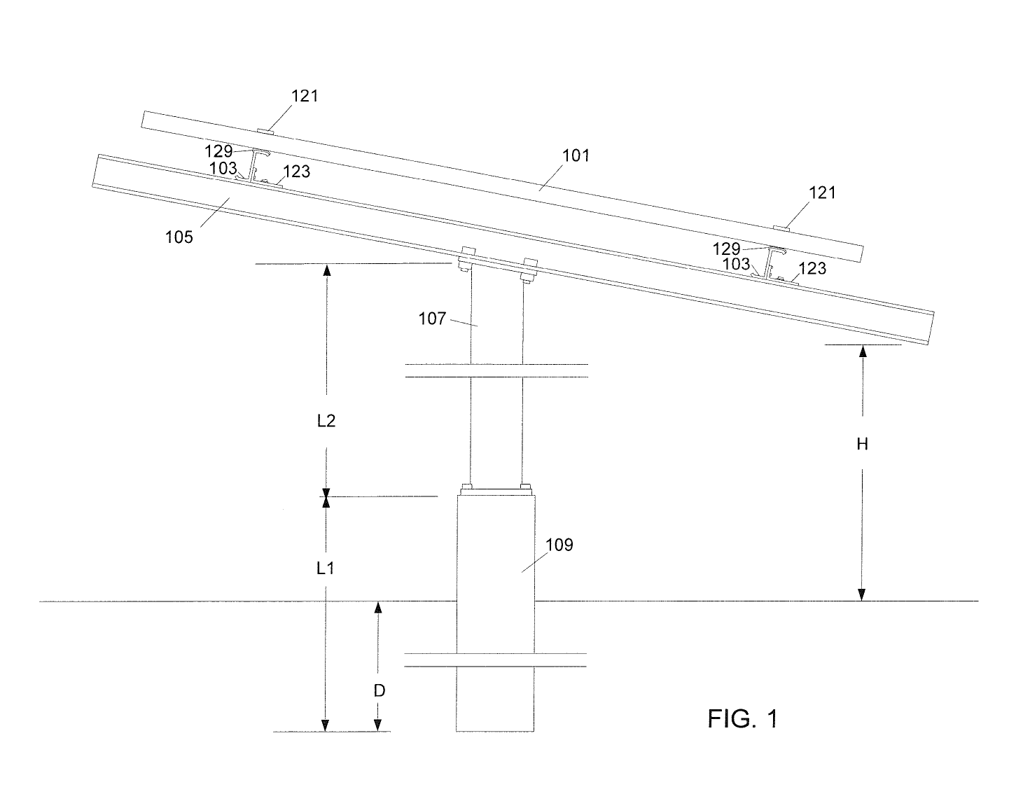

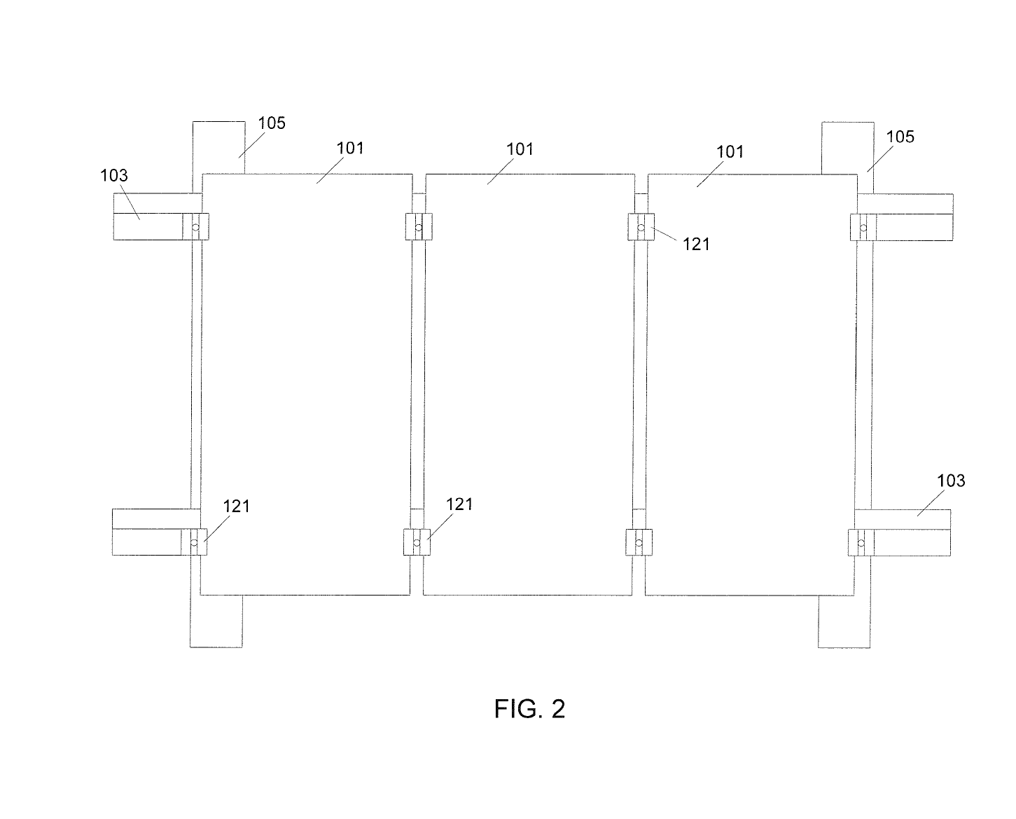

With reference to FIGS. 1 and 2, the basic components of an embodiment of the solar module mounting system are illustrated. FIG. 1 is a side view that shows the solar modules 101 secured to purlins 103 with module clips 121. The purlins 103 are coupled to purlin clips 123 that are mounted on beams 105. The beams are mounted on posts 107 which can vary in height H. For example, if the solar modules 101 are mounted close the ground the height H may be about 1 to 4 feet. However, if the solar modules 101 are elevated to allow the space under the modules to be utilized for parking the height H can be 7 to 15 feet. There can be a significant difference in physical loads that are applied to the foundation 109 and/or post 107 based upon the height H of the solar modules. In order to properly support the solar module structure, the bottoms of the posts 107 can be secured to a foundation 109 which can be concrete, steel, structural steel, piles or other suitable foundation systems that are at least partially buried.

The depth D of the foundation 109 and bending strength of the post 107 can depend upon the length of the foundation L1 and the length of the post L2 as well as the weight of the structure as well as the surface area of the solar modules and ambient weather conditions including: wind, rain, snow, storm activity, etc. The posts 107 can be vertically oriented and the I-beams 105 can be mounted at an angle on the posts 107 depending upon the optimum solar module 101 exposure angle.

FIG. 2 is a top view which shows the solar modules 101 mounted on purlins 103 that extend under the widths of the solar modules 101. The solar modules 101 can be clamped to the purlins 103 with module clips 121 that are held to the purlins 103 with threaded fasteners such as screws or bolts. The purlins 103 are mounted on the beams 105. The beams 105 can be high strength elongated structures and have a cross section such as “I”, “C” and “Z” or other suitable shapes.

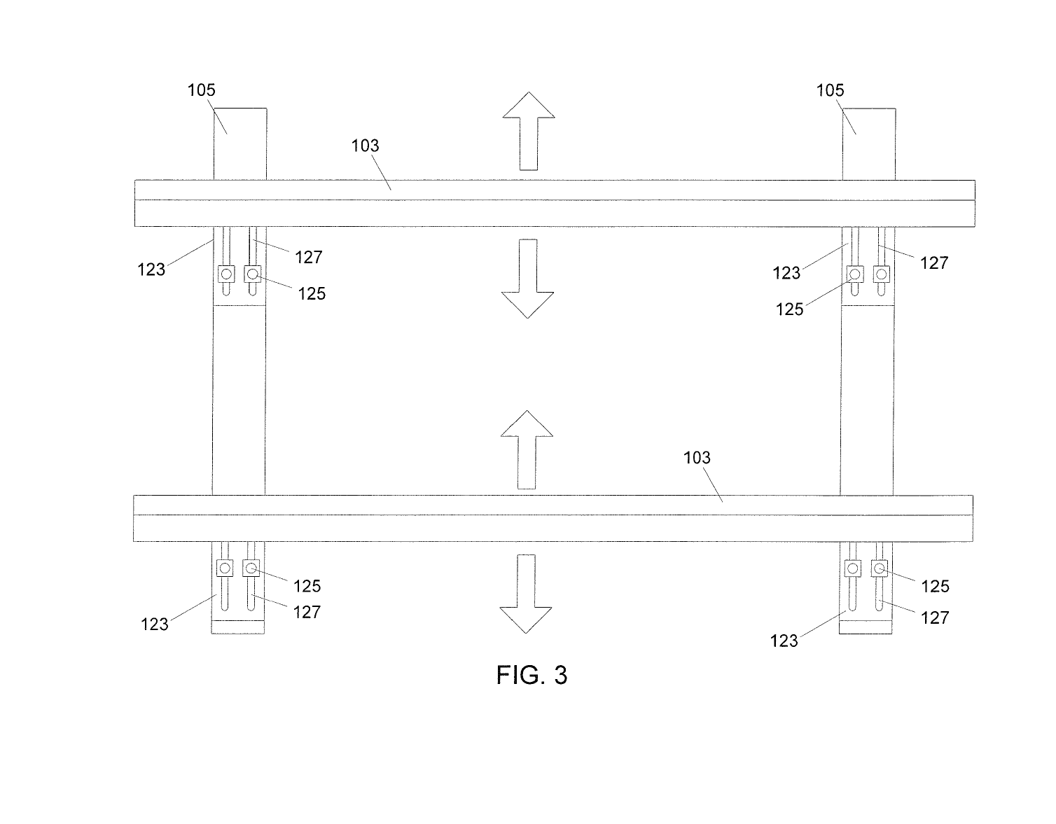

With reference to FIG. 3, a top view of the solar module mounting system is illustrated with the modules 101 removed so that an embodiment of the purlin clips 121 are more clearly illustrated. The purlins 103 can be coupled to the purlin clips 121 that are coupled to the beams 105 with bolts 125. The purlin clips 121 can include slots 127 so that the bolts 125 can be loosened and the purlins 103 can be moved along the length of the beams 105 to the desired positions based upon the solar modules being used. The positional movement of the purlins 103 can be up to the length of the slots 127. For example, in an embodiment, the beams 105 can be about 32 to 38 feet long and the holes in the beam can configured in 3 pairs with each pair separated by about 2 to 3 inches and the pairs spaced along the beam 105 at intervals of about 40 to 44 inches and 23 to 26 inches. The lengths of the slots 127 can be about 2.5 to 3.5 inches.

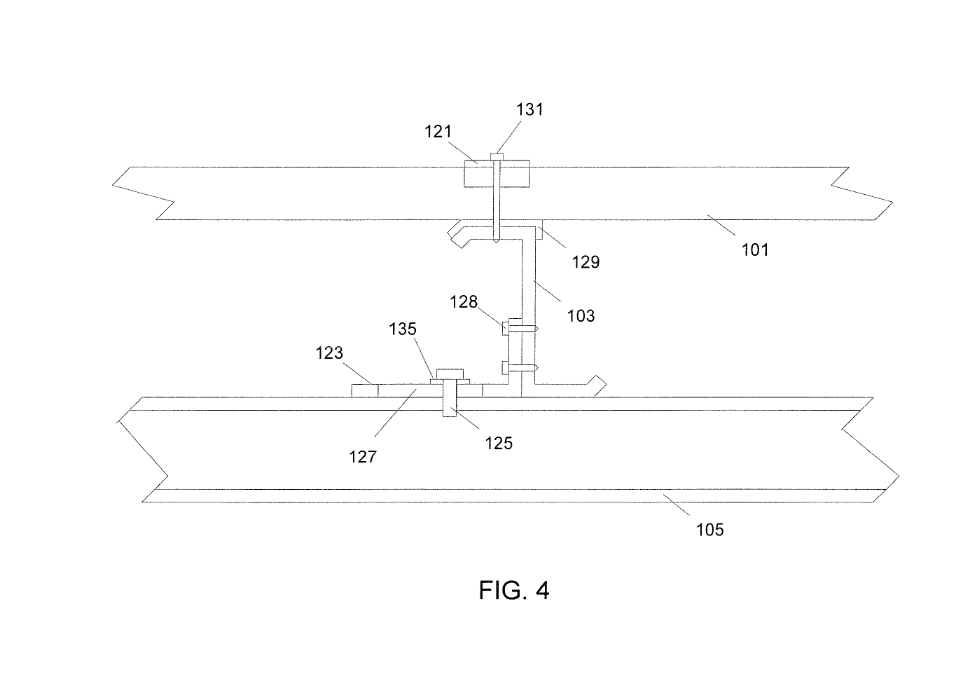

FIG. 4 illustrates a cross sectional view of an embodiment of the solar module mounting system at a junction of the beam 105 and the purlin 103. The purlin clip 123 can have holes and the purlin 103 can be coupled to the purlin clip 123 with a plurality of fasteners 128 which can be threaded self drilling fasteners which drills and taps the side portion of the purlin 103. In other embodiments, the fastener 128 can be a threaded bolt that is secured to the purlin 103 with a nut having a mating thread. The fastener 128 can be tightened to a predetermined torque to properly secure the purlin clip 123 to the purlin 103. A bolt 125 is placed through a washer 135 and the slot 127 in the purlin clip 123 and the bolt 125 can be threaded into a tapped hole in the beam 105. The purlin 103 and purlin clip 123 can then be positioned on the beam 105 and the bolt 125 can be tightened to secure the purlin 103 to the beam 105. The purlins 103 can span a distance of about 18 to 31 feet between the adjacent beams. The profile, size and strength of the purlins 103 can be based upon the span between beam 105 supports and the design criteria which can include wind loading and other design factors.

The solar module 101 is secured to the purlin 103 with a module fastener 131 which extends through a module clip 121, a module spacer 129 and the upper portion of the purlin 103. The lower surface of the module spacer 129 can be shaped to match the upper portion of the purlin 103 for a secure fit. The module clip 121 and module spacer 129 components will be described in more detail later. In an embodiment, the purlin 103 can have a “Z” cross section and the fastener 131 can be a self-drilling fastener which drills and taps the upper portion of the purlin 103. In other embodiments, the fastener 131 can be a threaded bolt that is secured to the purlin 103 with a nut having a mating thread. The fastener 131 can be tightened to a predetermined torque to properly secure the module 101 to the purlin 103. In an embodiment, the purlin 103 can have a “C” or “I” cross section.

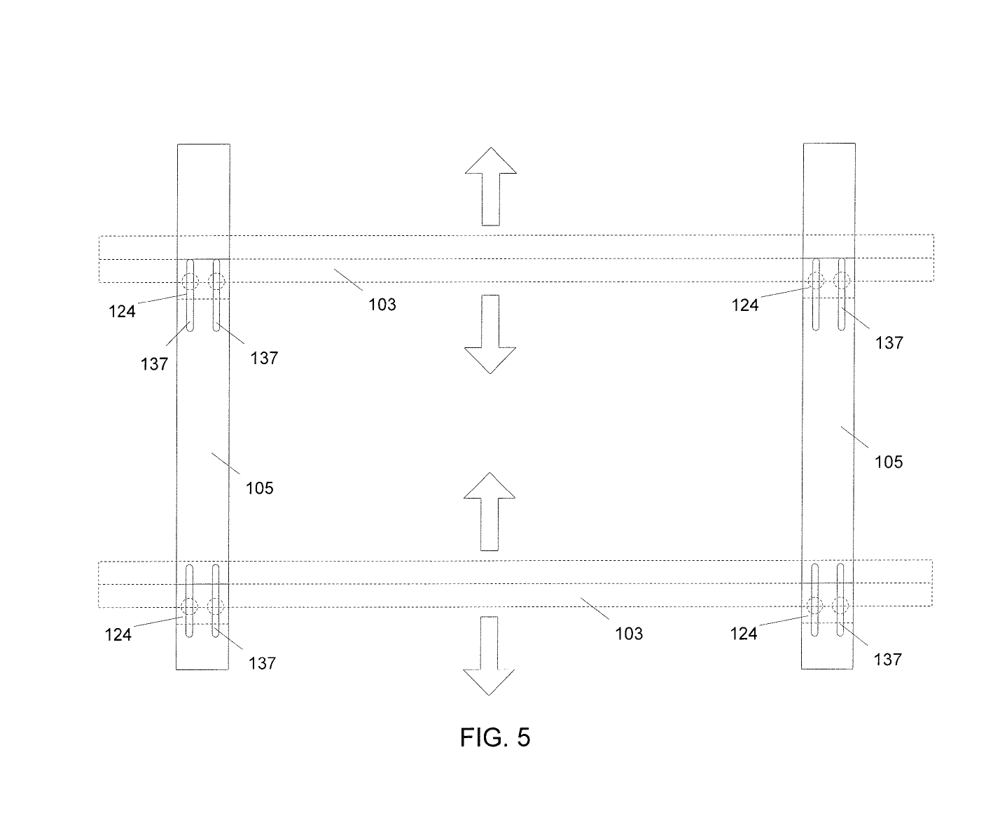

FIG. 5 illustrates a top view of an alternative embodiment of the solar module mounting system. In this illustration, the purlins 103 and purlin clips 121 are only shown in dashed lines. The beams 105 can have slots 137 and the bolts 125 that secure the purlins 103 to the beams 105 can pass through the slots 137. Again, the bolts 125 can be loosened so that the purlins 103 can be moved to the desired positions on the beams 105 based upon the solar modules being used. The length of the beam 105 in this embodiment can also be about 32 to 38 feet long and the positions of the pairs of slots 137 can be spaced along the beam at intervals of about 37-40 inches and 26-30 inches. The slot lengths can be about 7.5 to 10 inches.

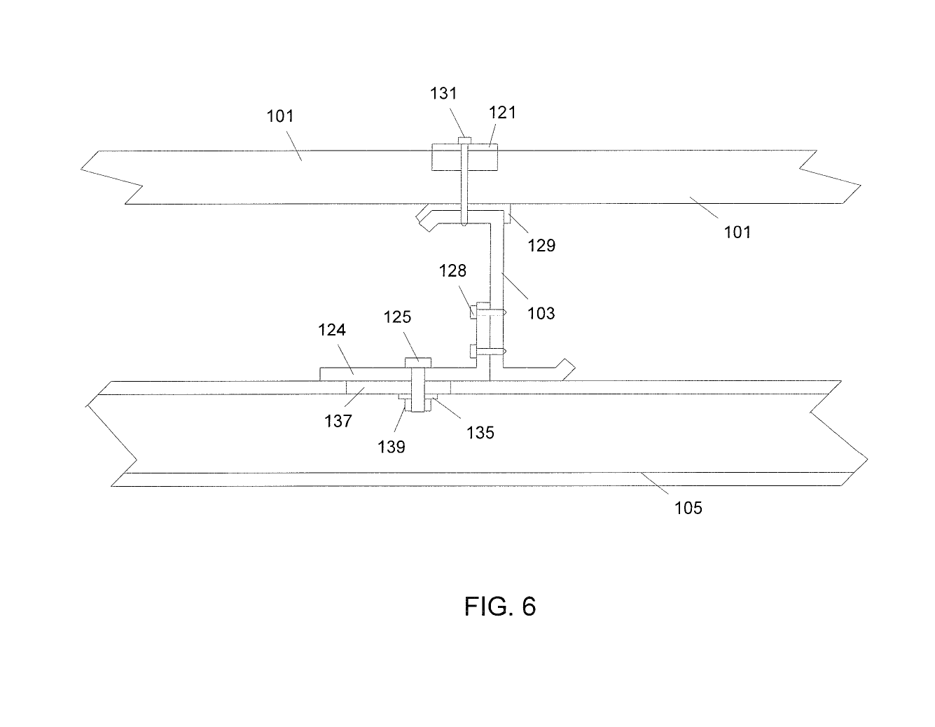

FIG. 6 illustrates a cross sectional view of the FIG. 5 embodiment of the solar module mounting system at a junction of the beam 105 and the purlin 103. The purlin clip 124 can have holes and the purlin 103 can be coupled to the purlin clip 123 with a plurality of fasteners 128 as described with reference to FIG. 4. A bolt 125 is placed through the slot 137 in the beam 105 and the washer 135. The bolt 125 can then be threaded into a nut 139 having a mating thread. The purlin 103 and purlin clip 124 can then be positioned on the beam 105 and the bolt 125 can be tightened with the nut 139 to secure the purlin 103 to the beam 105. In an embodiment, the bolt 125 and nut 139 can be tension control bolts or “TC Bolts” which use a special tool that grasps both the nut 139 and bottom portion of the bolt 125. The tool can tighten the nut 139 onto the bolt 125 and when the predetermined torque is reached, the bottom portion of the bolt 125 can break in shear to prevent further torque being applied.

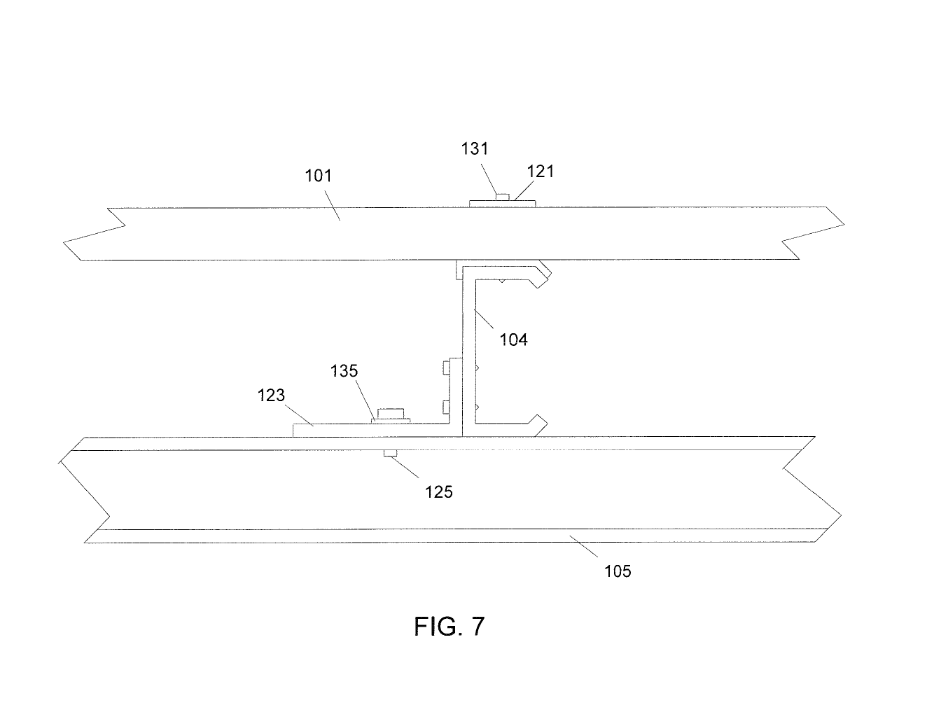

With reference to FIG. 7, a cross section of another embodiment of the mounting system is illustrated. Rather than having a “Z” cross section, in the illustrated embodiment the purlin 104 has a “C” cross section. The other components can be the same as described above with reference to FIGS. 4 and 6. In an embodiment, the purlin 103 can have an “I” cross section.

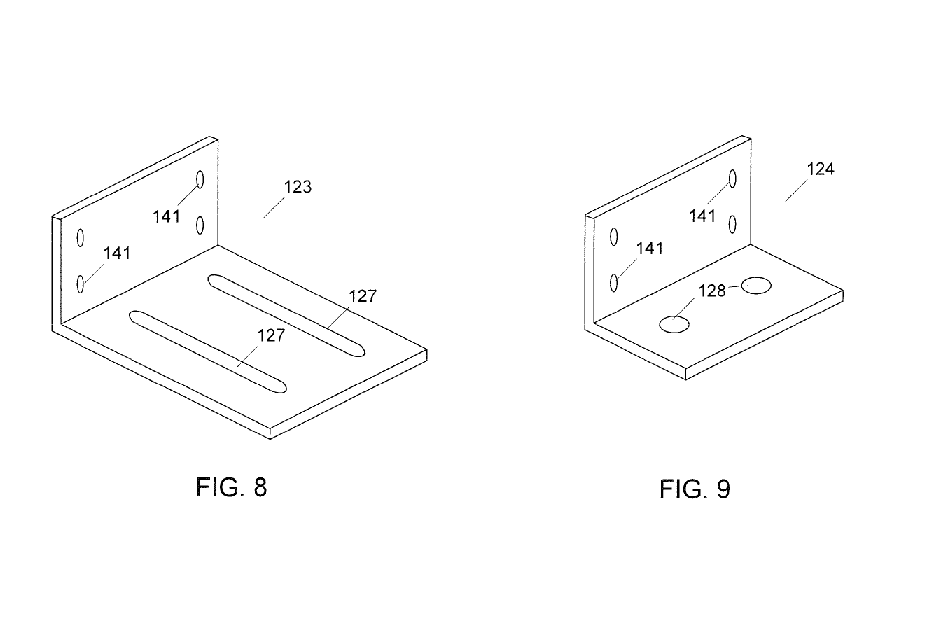

With reference to FIG. 8, an embodiment of the purlin clip 123 is illustrated. The purlin clip 123 can have an “L” cross section that has a horizontal portion that has slots 127 and a vertical portion that has a plurality of holes 141. As discussed above with reference to FIG. 4, the purlin clip 123 is secured to the purlin with fasteners that are placed through the holes 141 and secured to the beam with bolts that are placed through the slots 127.

With reference to FIG. 9, an alternative embodiment of the purlin clip 124 is illustrated. The purlin clip 124 can also have an “L” cross section that has a horizontal portion that has holes 128 and a vertical portion that has holes 141. As discussed above with reference to FIG. 6, the purlin clip 124 is secured to the purlin with fasteners that are placed through the holes 141 and secured to the beam with bolts that are placed through the holes 128.

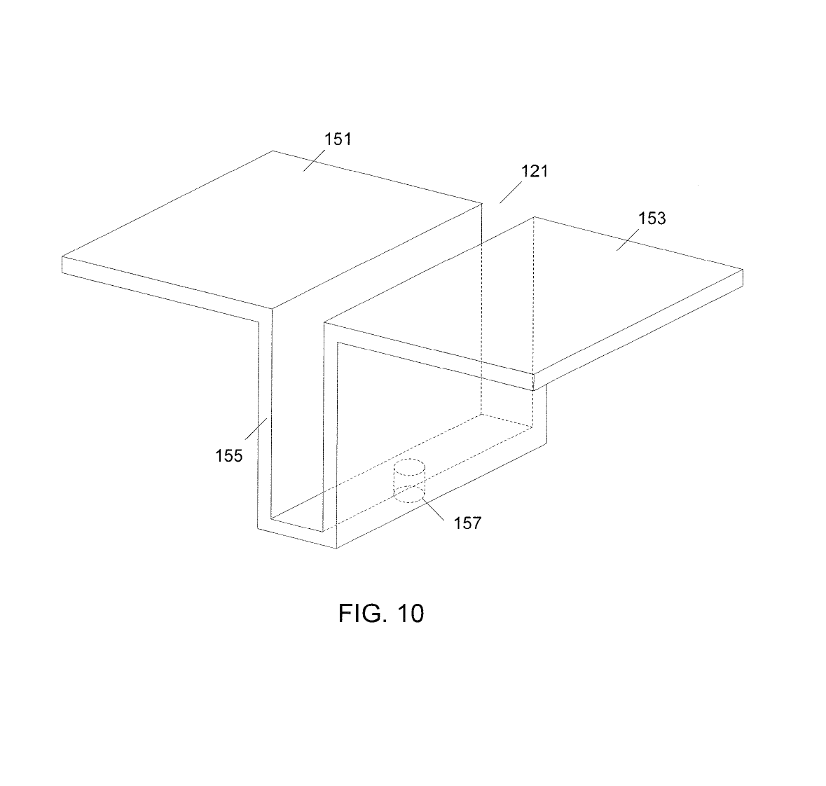

The solar modules are secured to the mounting system with a set of fixtures which clamp the upper and lower edges of the solar modules to the purlins. As illustrated in FIGS. 4 and 6, the fixtures include module fasteners 131, module clips 121 and spacer clips 129. FIG. 10, is a more detailed illustration of the module clip 121 which includes a first clamp portion 151, a second clamp portion 153 and a vertical spacer portion 155. The first clamp portion 151 engages a top surface of a solar module and the second clamp portion 153 engages a top surface of an adjacent solar module. The spacer portion 155 can fit between and against the edges of the adjacent solar modules. The spacer portion 155 can include a through hole 157 through which the module fastener 131 can be placed.

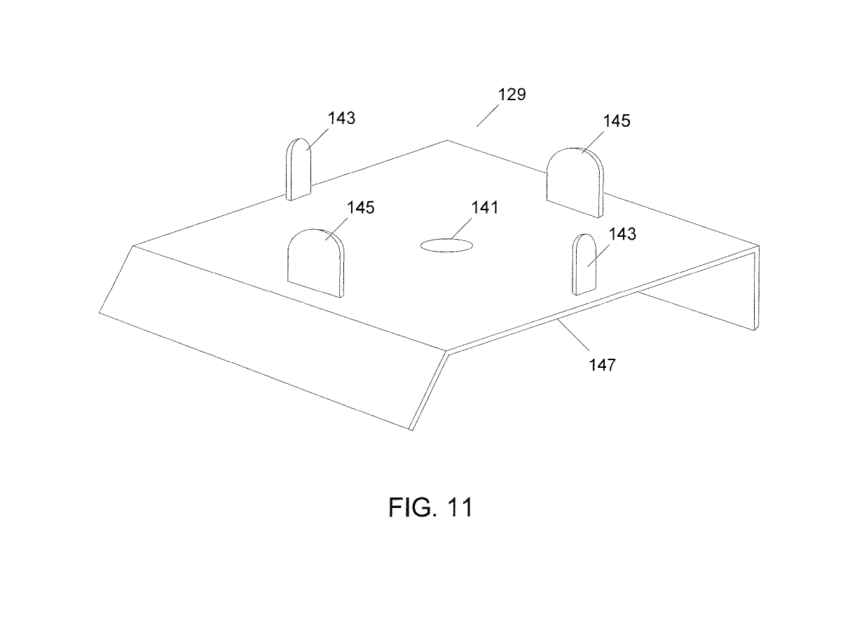

With reference to FIG. 11, an embodiment of the spacer clip 129 is illustrated. Spacer clips 129 function to secure the solar modules to the purlins and properly separate the adjacent solar modules from each other. The spacer clip 129 has a lower surface 147 that corresponds to the upper surface of the purlin. The upper surface of the spacer clip 129 can include a center hole 141, spacer tabs 145 and module engagement tabs 143. As illustrated in FIGS. 4 and 6, the fasteners used to secure the solar modules to the purlins pass through the center holes 141 of the spacer clips 129. The spacer clips 129 are placed under the solar modules with the spacer tabs 145 positioned between the facing edges of the adjacent solar modules. The spacer tabs 145 can ensure the proper spacing of the solar modules on the mounting system. The engagement tabs 143 can fit into holes on the bottom of the solar modules and can prevent the solar modules from sliding relative to the spacer clips 129.

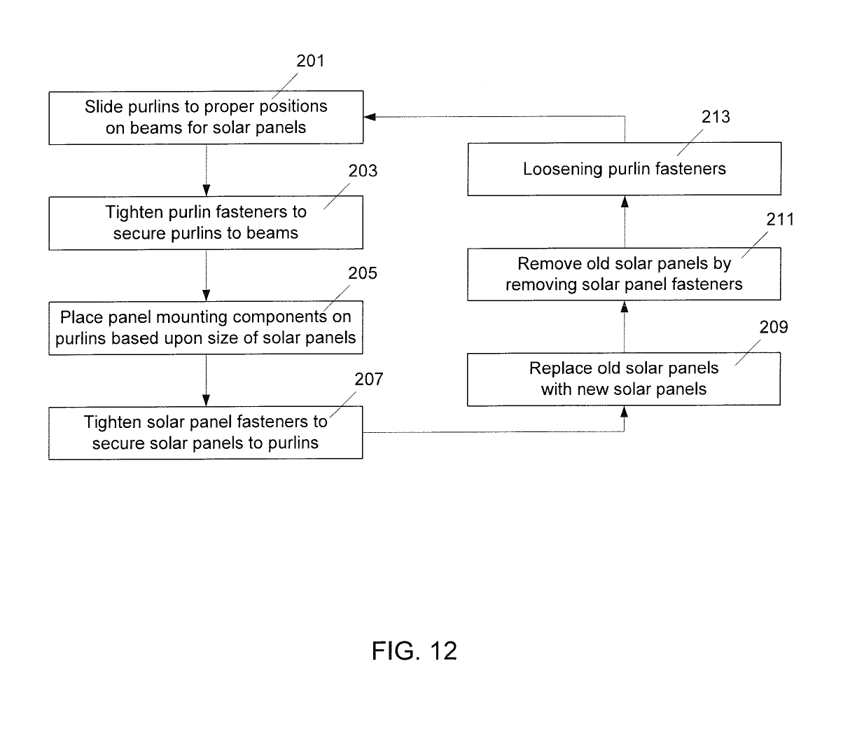

A benefit of the inventive system is the ability to adapt to various solar module sizes. FIG. 12 is a flow chart illustrating the process used to install and change solar modules using the inventive system. The purlins and purlin clips are placed on the beams and slid to the proper positions for the solar modules 201. The purlin fasteners are tightened to secure the purlins in the proper positions 203. The mounting components including the module clips and spacer clips are moved to the proper positions on the purlins based upon the size of the solar modules 205. The solar modules are placed between the mounting components and the module fasteners are tightened to secure the solar modules to the mount 207. The solar module installation can be completed and the energy produced by the solar modules can be used. Eventually, the solar modules may need to be replaced with newer more efficient modules 209. The old solar modules can be removed by loosening and removing the solar module fasteners 211. With the old solar modules removed, the purlin fasteners can be loosened 213. The process described in steps 201-207 can be repeated to install the new solar modules.

The inventive system can be used for various types of installations. As illustrated in FIG. 1, the beams 105 that support the solar modules 101 can be mounted on the tops of vertical posts 107 which can be attached to foundations which are at least partially buried in the ground. In alternative embodiments, the posts 107 can be elongated steel structures which are driven into the ground without a foundation. The solar modules 101 can be mounted at various different heights H depending upon the type of installation. However, as the height increases, the strength of the post 107 and foundation 109 will also need to increase. This increased strength can be necessary, particularly in areas where there are strong winds. Because the solar modules 101 are large flat surfaces, the wind blowing against the solar modules 101 can produce a significant amount of force and the height of the post 107 can act as a moment arm that increases the bending forces on the post 107 and foundation 109. In many areas, the solar module assembly must be fabricated to withstand specific wind velocities. Thus, the strength of the posts 107 and foundations 109 will be proportional to the height H of the solar modules 101. For example, if the H is less 3 feet, the post will be exposed to much less moment force than if the H is 13 feet or more. Because the forces are significantly different the construction and strength of the posts and foundations in these installations can be significantly different. For example for lower height and low wind criteria installations a post 107 that has a cross sectional width or diameter of about 3 inches can be used. However, for tall height and high wind installations, a post 107 having a width or diameter of 12 inches or greater can be used. The post 107 can be made of steel, aluminum or other similar suitable materials. The foundation 109 for the post 107 can be concrete that is case in place drilled, auger-cast drilled, pre-cast, or other suitable installations. Alternatively, the foundation can be steel in the form of driven piles, screwed piles, soil-nails or other similar steel foundation products. The relationship between the post and foundation strengths can be based upon the site engineering criteria with taller and larger installations requiring larger and stronger foundations 109 and posts 107.

It will be understood that the inventive system has been described with reference to particular embodiments, however additions, deletions and changes could be made to these embodiments without departing from the scope of the inventive system. Although the order filling apparatus and method have been described include various components, it is well understood that these components and the described configuration can be modified and rearranged in various other configurations.

What is claimed is:

1. An adjustable apparatus for rigidly coupling a solar module to a plurality of beams comprising:
a plurality of purlins;
a plurality of purlin clips, each of purlin clips having a vertical portion that is rigidly coupled to one of the purlins and a horizontal portion that is rigidly coupled to one of the beams;
a plurality of spacer clips, each of the spacers having a lower surface that is rigidly coupled to an upper surface of one of the purlins and an upper surface that is rigidly coupled to a bottom surface of the solar module; and
a module clip having a portion that is rigidly coupled to an upper edge of the solar module.

2. The apparatus of claim 1 wherein the horizontal portion of each of the purlin clips includes a slot that is aligned with the length of one of the beams.

3. The apparatus of claim 1 wherein the horizontal portion of each of the purlin clips includes two or more parallel slots that are aligned with the length of one of the beams.

4. The apparatus of claim 1 wherein each of the beams includes one or more slots and one of the purlin clips is rigidly secured to the beams over each of the slots.

5. The apparatus of claim 1 wherein each of the beams includes two or more adjacent parallel slots and one of the purlin clips is rigidly secured to the beams over each of the adjacent parallel slots.

6. The apparatus of claim 1 wherein the purlin clips are rigidly attached to the beams with threaded fasteners.

7. The apparatus of claim 1 wherein the plurality of purlins have an “I” cross section, a “Z” cross section or a “C” cross section.

8. The apparatus of claim 1 wherein the spacer clip includes a spacer tab extending upward from an upper surface of the spacer clip and a lower edge of the solar module is adjacent to the spacer tab.

9. The apparatus of claim 1 wherein the spacer clip includes an engagement tab extending upward from an upper surface of the spacer clip and the engagement tab is positioned within a recess on a lower surface of the solar module.

10. The apparatus of claim 1 further comprising:
a plurality of module fasteners, each of the module fasteners is positioned through one of the module clips and one of the spacer clips.

11. An adjustable apparatus for rigidly holding a solar module comprising:
a plurality of posts that each extend vertically from a surface;
a plurality of beams, each beam is coupled to an upper end of one or more of the plurality of posts and extends horizontally;
a plurality of purlins that are coupled to two or more of the plurality of posts;
a plurality of purlin clips, each of purlin clips having a vertical portion that is rigidly coupled to one of the purlins and a horizontal portion that is rigidly coupled to one of the beams;
a plurality of mounting components for securing the solar module to two more of the plurality of purlins.

12. The apparatus of claim 11 wherein the horizontal portion of each of the purlin clips includes a slot that is aligned with the length of one of the beams.

13. The apparatus of claim 11 wherein the horizontal portion of each of the purlin clips includes two or more parallel slots that are aligned with the length of one of the beams.

14. The apparatus of claim 11 wherein each of the beams includes one or more slots and one of the purlin clips is rigidly secured to the beams over each of the slots.

15. The apparatus of claim 11 wherein each of the beams includes two or more adjacent parallel slots and one of the purlin clips is rigidly secured to the beams over each of the adjacent parallel slots.

16. The apparatus of claim 11 wherein the purlin clips are rigidly attached to the beams with threaded fasteners.

17. The apparatus of claim 11 wherein the plurality of purlins have an “I” cross section, a “Z” cross section or a “C” cross section.

18. The apparatus of claim 11 wherein the plurality of mounting components includes a spacer tab that is adjacent to a lower edge of the solar module.

19. The apparatus of claim 11 wherein the plurality of mounting components includes an engagement tab that is positioned within a recess on a lower surface of the solar module.

20. The apparatus of claim 11 further comprising:
a plurality of module fasteners, each of the module fasteners is positioned through one of the module clips and one of the spacer clips.
